(19) United States
(12) Patent Application Publication
(10) Pub. No.: US 2023/0298966 A1
(43) Pub. Date: Sep. 21, 2023

(54) HEAT EXCHANGE SYSTEM

(71) Applicant: KENMEC MECHANICAL ENGINEERING CO., LTD., Taipei City (TW)

(72) Inventors: Ching-Fu HSIEH, Taipei City (TW); Shih-Chen CHANG, Taipei City (TW)

(73) Assignee: KENMEC MECHANICAL ENGINEERING CO., LTD., Taipei City (TW)

(21) Appl. No.: 17/892,140

(22) Filed: Aug. 22, 2022

Related U.S. Application Data
(60) Provisional application No. 63/320,690, filed on Mar. 16, 2022.

(30) Foreign Application Priority Data
Jun. 2, 2022 (TW) 111120766

(51) Int. Cl. H01L 23/473

(52) U.S. Cl. CPC H01L 23/473

(57) ABSTRACT

The present disclosure relates to a heat exchange system, which includes a cabinet and a heat exchange apparatus. The cabinet includes a heat dissipation door and a cabinet body, and the heat dissipation door is disposed on the cabinet body. The heat exchange apparatus is partially disposed in the cabinet body. The heat exchange apparatus includes a heat exchange module. The heat exchange module includes a first circulation pipe and a cooling device. The first circulation pipe is in fluid communication with a heat dissipation tube component in the heat dissipation door. The cooling device includes a second circulation pipe and a chilling machine. A part of the second circulation pipe is penetrated in the chilling machine to transfer heat into the chilling machine. The first circulation pipe is heat-exchanged with but not in fluid communication with the second circulation pipe.

### CROSS REFERENCE TO RELATED DISCLOSURE

This application claims the priority benefit of U.S. Provisional Application No. 63/320,690, filed on Mar. 16, 2022, and TW Patent Application Number 111120766, filed on Jun. 2, 2022, the full disclosure of which is incorporated herein by reference.

### BACKGROUND

### Technical Field

The present disclosure is related to a heat exchange system, and in particular, a heat exchange system that may stably realize the dissipation function.

### Related Art

In order to provide users with more convenient services, the number of central processing unit (CPU) disposed in the server is increasing, or at least the computing ability thereof is getting better and better. In addition, the number and/or performance of components such as a graphics processing unit (GPU), a hard disk, a power supply, a memory, etc. in the server is also increasing day by day. However, the increase in the number of components and/or the increase in performance also results in a large amount of waste heat.

In order to allow the servers installed in the cabinets to be in a normal working environment, a water cooling system is generally used today to quickly remove the heat generated by the servers during operation. However, not all computer rooms are able to be connected to the chilling machine of the building. Further, even if the water cooling system can be connected to the chilling machine of the building, the cooling water may deteriorate too much due to the piping of the chilling machine may be not maintained, or the cooling water may be polluted due to the chilling machine may be connected to other apparatus. Therefore, how to provide a heat dissipation system that can effectively help the servers in the cabinet to dissipate heat and can operate stably has become an urgent issue to be solved in the art.

### SUMMARY

The embodiments of the present disclosure disclose a heat exchange system, in order to solve the problem that the prior art cabinet is difficult to dissipate heat and can not operate stably.

In order to solve the above technical problems, the present disclosure is implemented as follows.

A heat exchange system is provided, which includes a cabinet and a heat exchange apparatus. The cabinet includes a heat dissipation door and a cabinet body, and the heat dissipation door is disposed on the cabinet body. The heat exchange apparatus is partially disposed in the cabinet body. The heat exchange apparatus includes a heat exchange module. The heat exchange module includes a first circulation pipe and a cooling device. The first circulation pipe is in fluid communication with a heat dissipation tube component in the heat dissipation door. The cooling device includes a second circulation pipe and a chilling machine. A part of the second circulation pipe is penetrated in the chilling machine to transfer heat into the chilling machine. The first circulation pipe is heat-exchanged with but not in fluid communication with the second circulation pipe.

In some embodiments, the heat exchange apparatus further includes a drive module, a buffer module, and a control module. The drive module is connected to the heat exchange module and is configured to drive a first fluid in the first circulation pipe to flow along the first circulation pipe. The buffer module is in fluid communication with the first circulation pipe. The buffer module includes a control valve and a storage space, and the control valve is located between the first circulation pipe and the storage space. The control module is disposed in the cabinet body. The control module is electrically connected to the drive module and the buffer module. The control module includes a sensing device, and the control module controls the control valve to open or close according to a sensing signal sent by the sensing device and controls the drive module according to the sensing signal sent by the sensing device.

In some embodiments, the control module includes a calculate sub-module and a record sub-module. The calculate sub-module receives the sensing signal from the sensing device, generates a control signal according to the sensing signal, and sends the control signal to the buffer module and/or the drive module. The record sub-module receives the sensing signal from the sensing device and stores a voltage information, a current information, a fluid pressure information, a fluid temperature information, and a fluid flow information of the sensing signal.

In some embodiments, the drive module includes a drive pump, and the drive pump is disposed in the first circulation pipe and drives the first fluid in the first circulation pipe.

In some embodiments, the drive pump is provided in plurality. At least one of the plurality of drive pumps is in a running state, and at least one of the plurality of drive pumps is in a closed state.

In some embodiments, the heat dissipation door includes a first plate, a plurality of heat dissipation sheets, and a heat dissipation tube component. The plurality of heat dissipation sheets is disposed on one side of the first plate adjacent to the cabinet body, and each of the plurality of heat dissipation sheets has a heat dissipation surface. The heat dissipation tube component is disposed on one side of the first plate adjacent to the cabinet body and includes a water inlet, a water outlet, and a plurality of heat dissipation tubes. One end of the water inlet is in fluid communication with the first circulation pipe. One end of the water outlet is in fluid communication with the first circulation pipe. Two ends of each of the plurality of heat dissipation tubes respectively are in fluid communication with the water inlet and the water outlet. Each of the plurality of heat dissipation tubes has a plurality of extending sections and at least one connecting section. The plurality of extending sections passes through the heat dissipation surfaces in sequence, and at least one connecting section is connected to ends on the same side of two adjacent extending sections.

In some embodiments, the dissipation surfaces are orthogonal to the plurality of extending sections.

In some embodiments, the plurality of heat dissipation sheets are in direct contact with the plurality of heat dissipation tubes.

In some embodiments, the plurality of heat dissipation tubes are disposed on the first plate in a vertical direction in sequence.

In some embodiments, the water outlet and the water inlet are on a side of the first plate adjacent to a ground or on a side of the first plate away from the ground.

In some embodiments, the heat dissipation door further includes a plurality of fans disposed between the plurality of heat dissipation sheets and the cabinet body or outside the first plate, and the plurality of fans correspond to the plurality of heat dissipation sheets.

In some embodiments, the heat dissipation door further includes a roller, wherein the roller is disposed on a side of the first plate adjacent to a ground.

In some embodiments, the heat dissipation door further includes a second plate body, and the second plate body is between the cabinet body and the first plate. An accommodating space is formed between the second plate body and the first plate, and the plurality of heat dissipation tubes and the plurality of heat dissipation sheets are in the accommodating space.

In some embodiments, the first plate and the second plate respectively have a plurality of air holes.

In the present disclosure, the heat exchange system transfers the heat out from the cabinet through the first circulation pipe and transfers the heat to the chilling machine through the second circulation pipe, thereby effectively dissipating heat. Wherein, there is only heat transfer between the first circulation pipe and the second circulation pipe without fluid communication. In this way, the second fluid flowing between the second circulation pipe and the chilling machine will not pollute the first fluid flowing between the first circulation pipe and the cabinet, thereby effectively extending the useful life of the entire heat exchange system. Therefore, the present disclosure realizes a heat exchange system that may effectively dissipate heat and operate continuously and stably.

### BRIEF DESCRIPTION OF THE DRAWINGS

The figures described herein are used to provide a further understanding of the present disclosure and constitute a part of the present disclosure. The exemplary embodiments and descriptions of the present disclosure are used to illustrate the present disclosure and do not limit the present disclosure, in which:

FIG. 1 is a block diagram of the heat exchange system according to an embodiment of the present disclosure.

FIG. 2 is a pipeline configuration schematic diagram of the heat exchange system according to an embodiment of the present disclosure.

FIG. 3 is a schematic diagram of the heat exchange system according to an embodiment of the present disclosure.

FIG. 4 is an another schematic diagram of the heat exchange system according to an embodiment of the present disclosure.

FIG. 5 is a schematic diagram of the cabinet and the heat dissipation door thereof according to the second embodiment of the present disclosure.

FIG. 6 is an exploded view of the heat dissipation door according to an embodiment of the present disclosure.

FIG. 7 is a schematic diagram of the fluid path according to an embodiment of the present disclosure.

### DETAILED DESCRIPTION OF THE EMBODIMENTS

In order to make the objectives, technical solutions, and advantages of the present disclosure clearer, the technical solutions of the present disclosure will be described clearly and completely in conjunction with specific embodiments and the figures of the present disclosure. Obviously, the described embodiments are only a part of the embodiments of the present disclosure, rather than all the embodiments. Based on the embodiments in the present disclosure, all other embodiments obtained by a person of ordinary skill in the art without creative work fall within the protection scope of this disclosure.

The following description is of the best-contemplated mode of carrying out the present disclosure. This description is made for the purpose of illustrating the general principles of the present disclosure and should not be taken in a limiting sense. The scope of the present disclosure is best determined by reference to the appended claims.

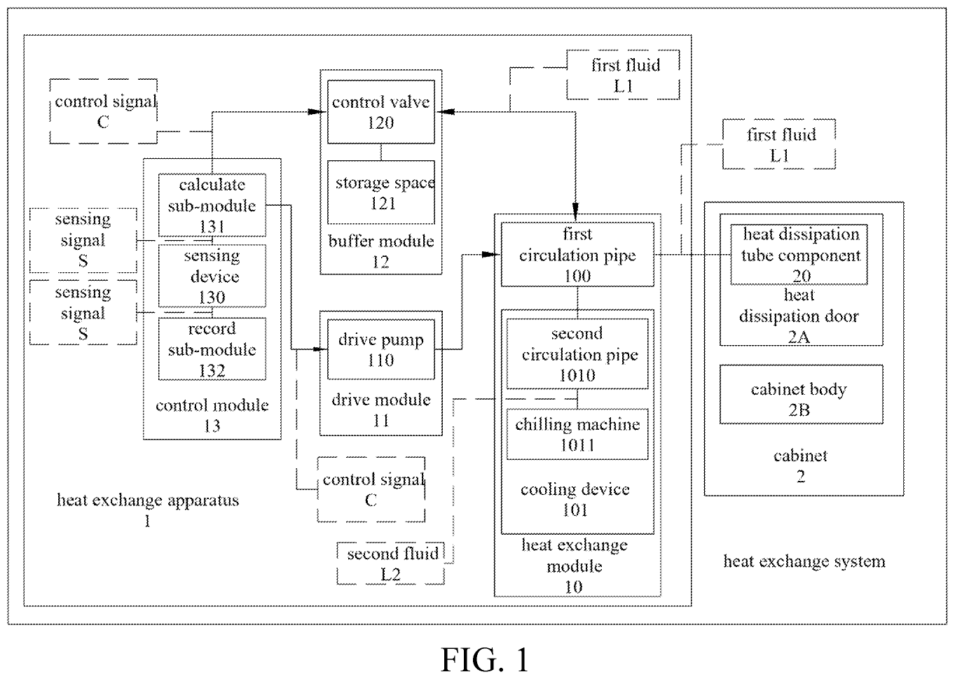

FIG. 1 is a block diagram of the heat exchange system according to an embodiment of the present disclosure. As shown in the figure, the heat exchange system includes a cabinet 2 and a heat exchange apparatus 1. In the present disclosure, the term “cabinet” refers to a carrier device in which a server is disposed. For example, the cabinet may be a server carrier device located in a computer room, and the server may include components such as a central processing unit, a graphics processing unit, a hard disk, a power supply, and a memory, but the present disclosure is not limited thereto. It should be noted that the present disclosure is not limited to the location of the cabinet.

As mentioned above, the heat exchange apparatus 1 is configured to remove heat from the cabinet 2. More specifically, the cabinet 2 includes a heat dissipation door 2A and a cabinet body 2B, and the heat dissipation door 2A is disposed on the cabinet body 2B. Wherein, the heat exchange apparatus 1 is connected to the heat dissipation door 2A of the cabinet 2, and carries away the heat of the heat dissipation door 2A and the cabinet body 2B by fluid.

In the present disclosure, the heat exchange device 1 may include a computing component with a miniaturized control module (such as the control module 13 mentioned below), so that the computing component including the module is disposed in the cabinet 2. In this way, the heat exchange device 1 of the present disclosure may not occupy a large volume and may improve heat dissipation for the cabinet 2 in which it is located. Furthermore, since each computing component only controls the heat dissipation process of one cabinet 2, the burden of the computing component may be significantly reduced.

Based on the above explanation, it may be understood that the heat exchange system of the present disclosure is composed of the cabinet 2 for carrying a server and a heat exchange apparatus 1 for heat dissipation. Further, in order to improve the understanding of the present disclosure, the specific configuration and operation of the heat exchange apparatus 1 and the cabinet 2 will be described hereinafter.

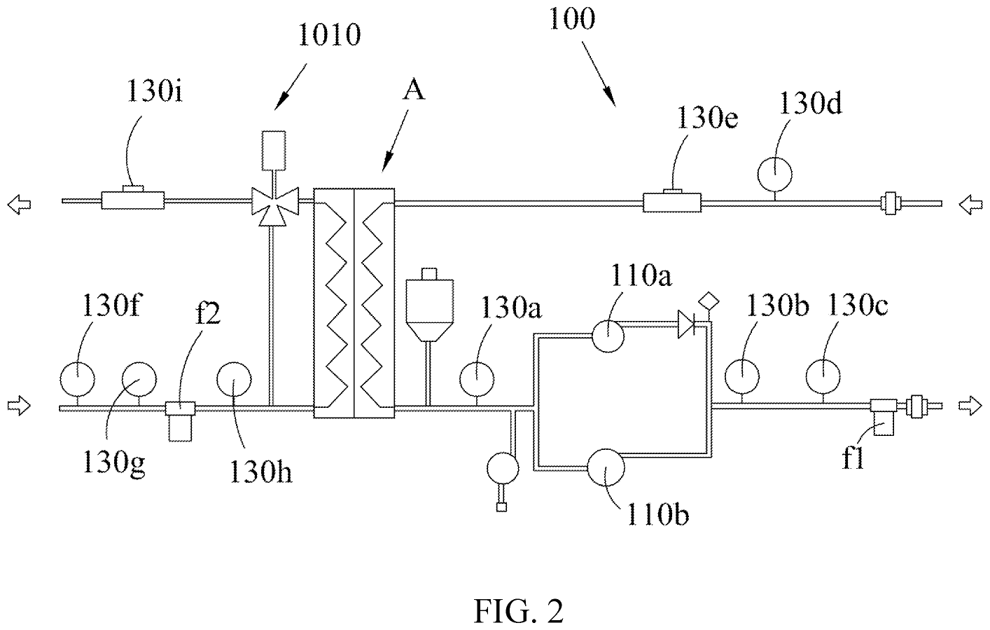

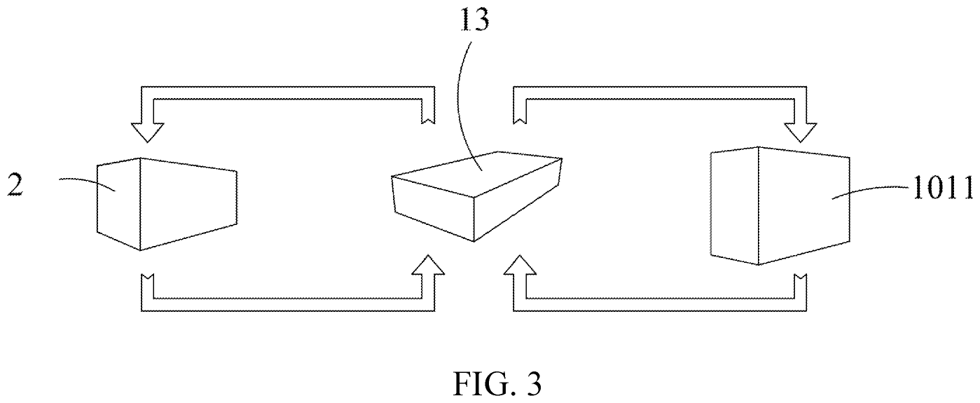

As shown in FIG. 2 and FIG. 3, which are a schematic diagram and a schematic diagram of the pipeline configuration of the heat exchange system according to an embodiment of the present application, respectively. As shown in the figure, the heat exchange apparatus 1 includes a heat exchange module 10, a drive module 11, a buffer module 12, and a control module 13. Wherein, the control module 13 is disposed in the cabinet body 2B, and the driving module 11 and the buffer module 12 may be disposed in the cabinet body 2B or outside the cabinet body 2B as required.

As shown in FIG. 1, the heat exchange module 10 includes a first circulation pipe 100, and the first circulation pipe 100 is in fluid communication with a heat dissipation tube component 20 of the heat dissipation door 2A. Wherein, a first fluid L1 is stored in the first circulation pipe 100. By making the first circulation pipe 100 connected to the heat dissipation tube component 20 of the heat dissipation door 2A, the first fluid L1 flowing along the first circulation pipe 100 may effectively remove the heat of the cabinet 2, so that the cabinet 2 may maintain a stable working temperature.

In some embodiments, the first fluid L1 may be water, aqueous glycol solution, or compatible cooling fluid. Preferably, the first fluid L1 may be deionized water. More preferably, the first fluid L1 is deionized water added with anti-corrosion inhibitors and bactericides, which may avoid reducing the heat dissipation capacity and reliability due to corrosion, scaling, and microbial growth of the pipeline. Still more preferably, the first fluid L1 is deionized water that may satisfy the following conditions:

| | | |
|---|---|---|
| Conductivity <1 uS/cm | Aluminum <0.05 mg/L | Potassium <0.01 mg/L |
| pH 6-8 | Antimony <0.1 mg/L | Magnesium <0.01 mg/L |
| Evaporation | Arsenic <0.1 mg/L | Manganese <0.01 mg/L |
| residue <10 mg/L | | |
| Turbidity <=1.0 NTU | Boron <0.05 mg/L | Molybdenum <0.01 |
| | | mg/L |
| Chloride such as | Barium <0.01 mg/L | Sodium <0.02 mg/L |
| chlorine <1.0 mg/L | | |
| Sulfates such | Calcium <0.01 mg/L | Nickel <0.01 mg/L |
| as calcium | | |
| carbonate <0.5 mg/L | | |
| Heavy metal | Cadmium <0.01 mg/L | Tin <0.1 mg/L |
| (Lead) <0.1 ppm | | |
| Silica <0.01 ppm | Chromium <0.01 mg/L | Zinc <0.01 mg/L |
| Nitrate <0.5 mg/L | Copper <0.01 mg/L | |
| Nitrite <0.5 mg/L | Iron <0.01 mg/L | |

In some embodiments, the first fluid L1 may also be a dielectric fluid that satisfies the following conditions:

| | Characteristic | | |
|---|---|---|---|
| | Fluorine | | Fluorine |
| | (single phase) | | (dual phase) |
| | First | Second | Third |
| | dielectric | dielectric | dielectric |
| Type | fluid | fluid | fluid |
| pH | 7 | 7 | 7 |
| Boiling Point (° C.) | 90 | 150 | 58 |
| Pour Point (° C.) | −90 | −60 | −90 |
| Flash Point | n/a | n/a | n/a |
| Density (G/Ml) | 1.74 | 1.83 | 1.6 |
| Water Capacity | <50 ppm | <50 ppm | <50 ppm |
| Kinematic Viscosity (Mm2/S | 10.65 | 1.5 | 0.59 |
| 22° C.) | | | |
| Surface Tension (Mn/M) | 15 | 13 | 13.6 |
| State | liquid | liquid | liquid |
| Appearance | colorless | colorless | colorless |
| Odor | very low | very low | very low |
| Specific Heat Capacity (J/Kg-K) | 1150 | 1100 | 1201 |
| Percentage of Volatile Matter | 100% | 100% | 100% |
| Dielectric Strength | >40 kv | >40 kv | >40 kv |
| Dielectric Constant | 1.97 | 2.02 | 2.03 |
| Ozone Depletion Potential (ODP) | 0 | 0 | 0 |
| Global Warming Potential (GWP) | 320 | 335 | 273 |
| Critical Temperature (° C.) | 220 | 235 | 215 |
| Evaporation Rate (G/Min/Dm²) | 0.017 | 0.009 | 0.299 |
| Density of Vaper | 9.7 | 10.2 | 9.2 |

In some embodiments, the first fluid L1 may also be a mineral oil that satisfies the following conditions:

| | |
|---|---|
| pH | 7.5 |
| Boiling Point (° C.) | 300 |
| Pour Point (° C.) | 20 |
| Flash Point | 220 |
| Density (G/Ml) | 0.825 |
| Water Capacity | 0 ppm |
| Kinematic Viscosity (Mm2/S 22° C.) | 42 |
| Surface Tension (Mn/M) | 47 |
| State | liquid |
| Appearance | colorless |
| Odor | very low |
| Specific Heat Capacity (J/Kg-K) | 2730 |
| Percentage of Volatile Matter | 0% |
| Dielectric Strength | >45 KV |
| Ozone Depletion Potential (ODP) | 0 |
| Global Warming Potential (GWP) | 0 |
| Critical Temperature (° C.) | 350 |

In some embodiments, the first fluid L1 may also be a coolant that satisfies the following conditions:

| Type | First Coolant | | Second Coolant | |
|---|---|---|---|---|
| pH | 6.5 | | 6.5 | |
| Boiling Point (° C.) | 103.6 | | 103.6 | |
| Freezing Point (° C.) | 0 | | −12 | |
| Thermal Conductivity (50° C.) | 0.556 | | 0.556 | |
| Specific Heat Capacity (50° C.) | 3.96 | | 3.96 | |
| Viscosity (50oc) | ppm 0.78 | | ppm 0.78 | |
| Flash Point | N/A | | N/A | |
| Toxicity | low | | low | |
| Corrosion Inhibitor | Yes | | Yes | |
| Fungicide | Yes | | Yes | |
| Sulfuric Acid | N/A | | N/A | |
| Chloride | N/A | | N/A | |
| Bacteria | <100 | CFU/ml | <100 | CFU/ml |
| Total Hardness | 20 | ppm | 20 | ppm |
| Conductivity | 50 | μs/cm | 50 | μs/cm |
| Total Suspended Solids | <3 | ppm | <3 | ppm |
| Evaporation Residue | 5000 | ppm | 5000 | ppm |

In some embodiments, the temperature range of the first fluid L1 is within 10° C. to 45° C., which needs to be above the environment dew point. For example, the temperature of the first fluid L1 may be 10° C., 15° C., 20° C., 25° C., 30° C., 35° C., 40° C., 45° C., or a value between the values mentioned above. In practical applications, the temperature of the first fluid L1 may be adjusted according to the environment temperature, the condition of the central processing unit (CPU), and/or the characteristics of the first fluid L1.

As shown in FIG. 1, the heat exchange module 10 further includes a cooling device 101, and the first circulation pipe 100 is heat-exchanged with the cooling device 101. More specifically, the cooling device 101 includes a second circulation pipe 1010 and a chilling machine 1011. A part of the second circulation pipe 1010 is penetrated into the chilling machine 1011 to transfer the heat to the chilling machine 1011. The first circulation pipe 100 is heat-exchanged with but not in fluid communication with the second circulation pipe 1010. Wherein, the second fluid L2 is stored in the second circulation pipe 1010.

In some embodiments, the chilling machine 1011 may be a large chilling machine 1011 of a commercial or industrial building type, which is disposed outside the building and conducts heat-exchanged through a cooling water tower. However, the present disclosure is not limited thereto, the chilling machine 1011 may also be a dedicated cooler or a dedicated cooling tower, which may also be disposed in a building.

In some embodiments, the second fluid L2 may include water or an aqueous glycol solution, but the present is not limited thereto. Preferably, the second fluid L2 may also contain deionized water. More preferably, the second fluid L2 is deionized water added with anti-corrosion inhibitors and bactericides. Still more preferably, the second fluid L2 may be the same as the first fluid L1 satisfying the conditions in the above table.

By letting the first fluid L1 and the second fluid L2 respectively circulate in the first circulation pipe 100 and the second circulation pipe 1010, and letting the first fluid L1 and the second fluid L2 be close to each other (area A in FIG. 2) to conduct heat-exchanged, the present embodiment effectively conducts the heat of the cabinet 2 from the first fluid L1 and the second fluid L2 to the outside (for example, outside the building) in sequence. It should be noted that the first fluid L1 and the second fluid L2 of the present disclosure only use heat conduction and heat radiation for heat-exchanging, and at most indirect heat convection (for example, the air that may flow in the area A) for heat-exchanging. Which will not actually be in fluid communication with each other, so as to effectively prevent impurities and dirt from contaminating the first circulation pipe 100.

In this way, the present disclosure realizes a heat dissipation device with two independent fluid circuits. Through the above configuration, the two independent fluid circuits may not only exchange heat efficiently but also prevent impurities in one circuit from flowing into the other circuit.

As shown in FIG. 3, in some embodiments, taking the area A where the first circulation pipe 100 and the second circulation pipe 1010 perform heat exchange as a boundary, the heat exchange system of the present application may also be divided into a primary side and a secondary side. Take the right half of FIG. 3 as an example, components such as the second circulation pipe 1010 and the chilling machine 1011 are defined as the units of the primary-fluid-circuit. Take the left half of FIG. 3 as an example, components such as the the first circulation pipe 100 and the cabinet 2 are defined as the units of the secondary-fluid-circuit. That is, the present embodiment may be regarded as being composed of the fluid circuits on the left and right sides. Accordingly, the term “second” in the present disclosure in relation to the primary-fluid-circuit may also be referred to as “primary-fluid-circuit”. For example, elements such as “second circulation pipe”, “second fluid”, and “second filter device” (some components will be mentioned below) may be referred to as “primary-fluid-circuit circulation pipe”, “primary-fluid-circuit fluid”, and “primary-fluid-circuit filter device.

Similarly, the term “first” in the present disclosure in relation to the secondary-fluid-circuit may also be referred to as the “secondary-fluid-circuit”. For example, elements such as “first circulation pipe”, “first fluid”, “control valve” “storage space”, and “first filter”(some components will be mentioned below) may be referred to as “secondary-fluid-circuit circulation pipe”, “secondary-fluid-circuit fluid”, “secondary-fluid-circuit control valve”, “secondary-fluid-circuit storage space”, and “secondary-fluid-circuit filter”.

Obviously, the terms “first”, “second”, “primary-fluid-circuit”, and “secondary-fluid-circuit” used in the present disclosure are only used to distinguish different elements or components, which cannot be construed as indicating or implying relative importance or its sequential relationship.

As shown in FIG. 1, the drive module 11 is connected to the heat exchange module 10 and configured to drive the first fluid L1 in the first circulation pipe 100 to flow along the pipeline. In some embodiments, the drive module 11 includes a drive pump 110. The drive pump 110 is disposed in the first circulation pipe 100 and drives the first fluid L1 in the first circulation pipe 100. For example, the drive pump 110 may be a plunger pump of a pressure test pump, which uses a relief valve to control pressure and a throttle valve to control flow. However, the present disclosure is not limited thereto. Any pumps well known to a person having ordinary skills in the art may be applied to the present disclosure. For example, the drive pump 110 may also be a metering pump or other suitable pumps.

In some embodiments, the drive pump 110 is provided in plurality. At least one of the plurality of drive pumps 110 is in a running state, and at least one of the plurality of drive pumps 110 is in a closed state. FIG. 2 is a schematic diagram of the pipeline configuration of the heat exchange system according to an embodiment of the present disclosure, and the right half of FIG. 2 is a partial schematic diagram of the first circulation pipe 100. Take the present embodiment as an example, the number of drive pump 110 may be two, and the two drive pumps 110 (ie, the first drive pump 110a and the second drive pump 110b) are respectively connected in series in the first circulation pipe 100. When one of the two drive pumps 110 is in a running state, the other of the two drive pumps 110 is in a closed state. In this way, the entire drive module 11 only relies on one drive pump 110 to drive the delivery of the first fluid L1, while the other drive pump 110 is used for backup. In this case, the two drive pumps 110 may be turned off alternately at a fixed cycle to increase the service life of the apparatus. In addition, through the design of alternate activation, the drive module 11 may not affect the operation of the heat exchange system 1 during maintenance. It should be noted that the number mentioned above is only an example. In other embodiments, the number of drive pump 110 may also be three, four, or more than four, and at least one of the drive pumps 110 is in a closed state.

As shown in FIG. 1, the buffer module 12 is in fluid communication with the first circulation pipe 100, and the buffer module 12 includes a control valve 120 and storage space 121. The control valve 120 is located between the first circulation pipe 100 and the storage space 121. In the present disclosure, the storage space 121 may be a storage device such as a hollow liquid storage tank, a liquid storage bucket, etc., which is used for storing or replenishing the first fluid L1.

For example, when the environment temperature rises and the volume of the first fluid L1 increases, the control valve 120 may be set to open so that the first fluid L1 flows into the storage space 121 from the first circulation pipe 100. In this way, the parameters such as flow rate and pressure of the first fluid L1 in the first circulation pipe 100 may be adjusted according to preset or real time settings. Conversely, when the volume of the first fluid L1 decreases due to a sudden drop in the environment temperature, or when the flow and pressure of the first fluid L1 need to be increased to improve the heat dissipation performance, the control valve 120 may also be set to open so that part of the first fluid L1 flows into the first circulation pipe 100 from the storage space 121.

As shown in FIG. 1, the control module 13 is disposed in the cabinet body 2B of the cabinet 2. The control module 13 is electrically connected to the drive module 11 and the buffer module 12, and the control module 13 includes a sensing device 130. The control module 13 controls the control valve 120 to open or close according to a sensing signal S sent by the sensing device 130, and the control module 13 controls the drive module 11 according to the sensing signal S sent by the sensing device 130. In some embodiments, the sensing device 130 may include one or more of a voltage sensor, a current sensor, a fluid temperature sensor, a fluid pressure sensor, a fluid flow meter, and/or various types of sensors well known to a person having ordinary skills in the art to effectively monitor the status of the heat exchange module 10. Specifically, the fluid temperature sensor, the fluid pressure sensor, the fluid flow meter, and other suitable sensors generate the sensing signal S according to the measured state of the first fluid L1. The sensing signal S may include a voltage information, a current information, and a fluid pressure information, a fluid temperature information, and a fluid flow information, but the present disclosure is not limited thereto.

As shown in FIG. 2, the first circulation pipe 100 at the right half of the diagram may be provided/connected with the sensing devices 130 such as a fluid pressure sensor 130a, a fluid pressure sensor 130b, a fluid temperature sensor 130c, a fluid temperature sensor 130d, and a fluid flow meter 130e, and the drive pumps 110 such as the first drive pump 110a and the second drive pump 110b.

Wherein, the fluid pressure sensor 130a is used to sense the pressure of the first fluid L1 before being pressurized through the first drive pump 110a and/or the second drive pump 110b, and the fluid pressure sensor 130b is used to sense the pressure of the first fluid L1 after being pressurized through the first drive pump 110a and/or the second drive pump 110b. The fluid temperature sensor 130c is used to sense the temperature of the first fluid L1 after absorbing the heat of the cabinet 2 (ie, in the water return state), and the fluid temperature sensor 130d is used to sense the temperature of the first fluid L1 before absorbing the heat of the cabinet 2 (ie, in the water outlet state). The fluid flow meter 130e is used to sense the flow rate of the first fluid L1 in the first circulation pipe 100.

Through the configuration mentioned above, the control module 13 may accurately confirm the state of the first fluid L1 in the first circulation pipe 100, so as to control the drive module 11 and/or the buffer module 12 in real time. When one or more of the temperature, pressure, and flow rate of the first fluid L1 is abnormal, the control module 13 sends a control signal C according to the sensing signal S sent by the sensing devices 130 to control the drive module 11 to stop running, or control the control valve 120 to open/close to adjust the total amount of the first fluid L1 in the first circulation pipe 100.

It should be noted that the configuration mentioned above is only an example of the present disclosure, and the present disclosure is not limited thereto. In other embodiments, the first circulation pipe 100 may also be provided with/connected with other sensors of different types and numbers, so as to monitor the state of the heat exchange module 10 more effectively.

As shown in FIG. 2, the second circulation pipe 1010 at the left half of the diagram also may be provided/connected with sensing devices 130 such as a fluid pressure sensor 130g, a fluid pressure sensor 130h, a fluid temperature sensor 130f, and a fluid flowmeter 130i. The fluid pressure sensor 130g is used to sense the pressure of the second fluid L2. The fluid pressure sensor 130h is used to sense the pressure of the second fluid L2. The fluid temperature sensor 130f is used to sense the temperature of the second fluid L2 after absorbing the heat of the first fluid L1 (ie, backwater state). The fluid flow meter 130i is used to sense the flow rate of the second fluid L2 in the second circulation pipe 1010.

As shown in FIG. 1, in some embodiments, the control module 13 includes a calculate sub-module 131 and a record sub-module 132. The calculate sub-module 131 receives the sensing signal S from the sensing device 130, generates the control signal C according to the sensing signal S, and sends the control signal C to the buffer module 12 and/or the drive module 11. For example, the calculate sub-module 131 may include a suitable processor such as a central processing unit, a microprocessor, etc., which determines the state of the first fluid L1 according to a voltage information, a current information, a fluid pressure information, a fluid temperature information, and a fluid flow information of the sensing signal S, and generates the control signal C corresponding to the sensing signal S to the drive module 11 and/or the buffer module 12 to adjust the state of the first fluid L1 in the first circulation pipe 100.

The record sub-module 132 receives the sensing signal S from the sensing device 130, and stores the voltage information, the current information, the fluid pressure information, the fluid temperature information, and the fluid flow information of the sensing signal S. In the present disclosure, the record sub-module 132 may include a conventional hard disk drive (HDD), a solid state drive (SDD), a random access memory (RAM), an optical storage device (CD, DVD), or other suitable storage devices, to record the information mentioned above of the sensing signal S.

In some embodiments, the record sub-module 132 may also store a preset voltage information, a preset current information, a preset fluid pressure information, a preset fluid temperature information, and a preset fluid flow information. When the calculate sub-module 131 determines that the voltage information, the current information, the fluid pressure information, the fluid temperature information, and the fluid flow information detected in real time are different from the parameters mentioned above, the calculate sub-module 131 may adjust the drive module 11 and/or the buffer module 12 according to the situation, and/or issue an alarm to maintenance personnel.

In some embodiments, the heat exchange system may also include a filter, and the filter may be disposed on the first circulation pipe 100 and/or the second circulation pipe 1010 to effectively filter impurities in the pipeline. For example, the first circulation pipe 100 and the second circulation pipe 1010 may be respectively provided with a first filter f1 and a second filter f2, which are located at the positions shown in FIG. 2. However, the present disclosure is not limited thereto. Filters with different filtering levels may be disposed by a person having ordinary skills in the art according to requirements, and these filters may be disposed at positions different from those shown in FIG. 2.

Based on the above-described configuration, the present disclosure has provided an excellent heat exchange apparatus 1 that may continue to operate efficiently and stably. Hereinafter, the present disclosure also improves the heat dissipation door 2A of the cabinet 2, so that the heat dissipation door 2A may more effectively conduct the heat emitted by the server to the outside.

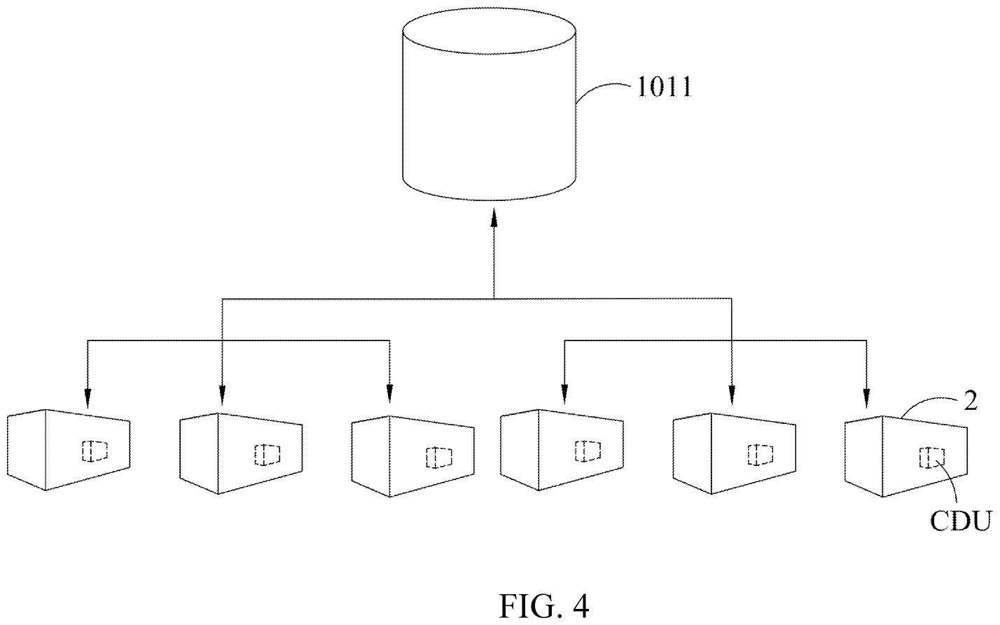

It should be noted that the above description is based on functions to distinguish the relationship between different elements. That is, the above description is only for the understanding of the present disclosure, and should not be regarded as a limitation of the present disclosure. As shown in FIG. 4, FIG. 4 is another schematic diagram of a heat exchange system according to an embodiment of the present disclosure. In some embodiments, the control module 13 in the heat exchange apparatus 1 may be disposed in the cabinet 2 and defined as a water-to-water stand-alone internal cooling distribution unit CDU. In other words, if the present disclosure is described in terms of its physical structure or appearance, the heat exchange system of the present disclosure may be roughly considered to be composed of the ice water machine 1011, the cooling distribution unit CDU, and the cabinet 2. Further, the chilling machine 1011 is installed on the roof of the building. The cooling distribution unit CDU is disposed inside the cabinet 2 and improves the heat dissipation for the cabinet 2. Besides, when a plurality of cabinets 2 are provided, the cooling distribution units CDU in the plurality of cabinets 2 may share one ice water machine 1011.

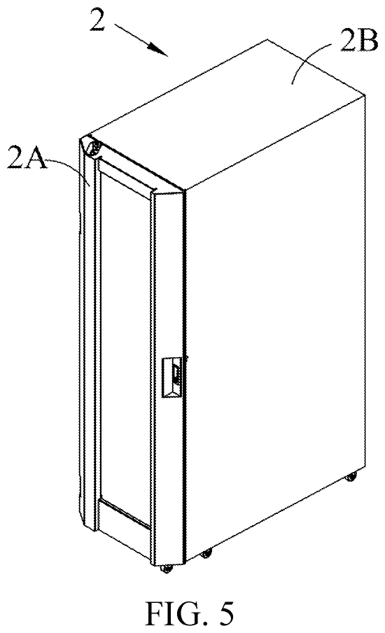

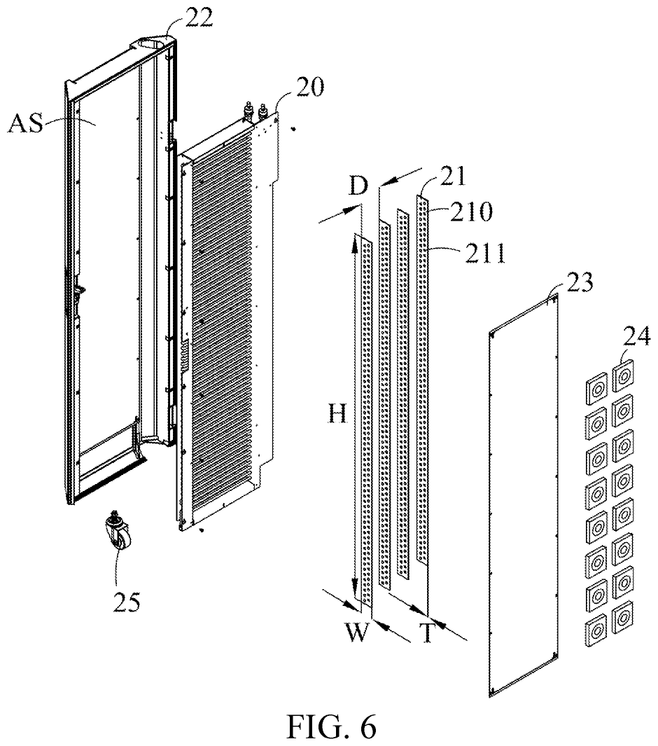

FIG. 5 and FIG. 6 are a schematic diagram and an exploded view of a cabinet of an embodiment according to the present disclosure. As shown in the figure, the heat dissipation door 2A includes a heat dissipation tube component 20, a plurality of heat dissipation sheets 21, and a first plate 22.

In some embodiments, the first plate 22 may be a flat door plate on which the plurality of heat dissipation sheets 21 and the heat dissipation tube component 20 are disposed. However, the present disclosure is not limited thereto. In some embodiments, the first plate 22 may also have an accommodating space AS, and the plurality of heat dissipation sheets 21, the heat dissipation tube component 20, and other components mentioned hereinafter are disposed in the accommodating space AS.

In some embodiments, the heat dissipation door 2A may also include a second plate 23, and the second plate 23 is between the cabinet body 2B and the first plate 22 (as shown in FIG. 6). An accommodating space AS is formed between the second plate 23 and the first plate 22, and the heat dissipation tube component 20 and the plurality of heat dissipation sheets 21 are in the accommodating space AS. By covering the heat dissipation tube component 20 and the plurality of heat dissipation sheets 21 with the first plate 22 and the second plate 23, these heat dissipation components may be effectively protected to prolong the service life of the device.

It should be noted that the heat dissipation door 2A of the present disclosure is composed of a door plate (eg, the heat dissipation sheets 21 and the heat dissipation tube component 20, etc.) and the heat dissipation components therein, and the door plate is used for carrying heat dissipation components. Therefore, any door plates (eg, the first plate 22 or the combination of the first plate 22 and the second plate 23 mentioned above) well known to a person having ordinary skill in the art may be used in the present disclosure. In the following, the heat dissipation door 2A including the first plate 22 and the second plate 23 will be used as an example for illustration, but the present disclosure is not limited thereto.

The plurality of heat dissipation sheets 21 are provided on a side of the first plate 22 adjacent to the cabinet body 2B, and each of the plurality of heat dissipation sheets 21 has a dissipation surface 210. More specifically, each heat dissipation sheet 21 has two dissipation surfaces 210 corresponding to each other, and the distance between the two dissipation surfaces 210 is a thickness T of the heat dissipation sheet 21. Wherein, the thickness T of the heat dissipation sheets 21 may be determined according to the actual use requirements. When the thickness T of the heat dissipation sheets 21 is larger, the heat capacity of the heat dissipation sheets 21 increases and the heat dissipation effect may be improved. Conversely, when the thickness T of the heat dissipation sheets 21 is smaller, the volume occupied by the heat dissipation sheets 21 decreases, so that more heat dissipation sheets 21 may be accommodated in the heat dissipation door 2A.

In some embodiments, the length of each heat dissipation sheet 21 in a vertical direction is a height H of the heat dissipation sheet 21. Wherein, the height H of the heat dissipation sheets 21 may be determined according to the actual use requirements. When the height H of the heat dissipation sheets 21 is larger, the heat capacity of the heat dissipation sheets 21 increases and the heat dissipation effect may be improved. It should be noted that the height H of the heat dissipation sheets 21 is preferably less than or equal to the length of the first plate 22 in the vertical direction to prevent the heat dissipation sheets 21 from exposing from the first plate 22.

In some embodiments, the length of each heat dissipation sheet 21 in a direction away from the first plate 22 is a width W of the heat dissipation sheet 21. Wherein, the width W of the heat dissipation sheets 21 may be determined according to the actual use requirements. When the width W of the heat dissipation sheets 21 is larger, the heat capacity of the heat dissipation sheets 21 increases and the heat dissipation effect may be improved. It should be noted that, when the heat dissipation door 2A has both the first plate 22 and the second plate 23, the width W of the heat dissipation sheets 21 is less than or equal to the distance between the inner surface of the first plate 22 (the surface away from the external environment) and the inner surface of the second plate 23 (the surface away from the cabinet body 2B).

In some embodiments, the plurality of heat dissipation sheets 21 are orthogonal to the inner surface of the first plate 22 and are sequentially disposed on the first plate 22 along a horizontal direction. In addition, the plurality of heat dissipation sheets 21 may also be orthogonal to the ground. It should be noted that the term “orthogonal” as used in the present disclosure refers to two elements (eg, the plurality of heat dissipation sheets 21 and the first plate 22) being substantially perpendicular to each other, which includes unexpected situations such as slight angles (eg, 0.1 degrees to 5 degrees) between the two elements due to tolerances or assembly processes.

In some embodiments, the plurality of heat dissipation sheets 21 may have a specific angle other than 0 degrees between the inner surface of the first plate 22, and/or the plurality of heat dissipation sheets 21 may be disposed on the first plate 22 in sequence along a specific direction other than the horizontal direction. By disposing the plurality of heat dissipation sheets 21 with the specific angles and/or the specific directions, the heat dissipation door 2A of the present disclosure may have more diverse configurations to be applied to cabinet bodies 2B of different types, shapes, and sizes, and the same excellent heat dissipation effect may be also achieved. It should be noted that the plurality of heat dissipation sheets 21 may have two or more than two specific angles or two or more than two specific directions at the same time. The present disclosure should not be limited to one specific angle or one specific direction.

In some embodiments, a specific separation distance D may be between two adjacent heat dissipation sheets 21. Wherein, the separation distance D between two adjacent heat dissipation sheets 21 (regarded as one group) may be the same or different from the separation distance D of another group. In the present disclosure, the term “separation distance D” refers to the distance between one side surface of the heat dissipation sheets 21 and the side surface of the adjacent heat dissipation sheets 21 on the same side. For example, the separation distance D between two adjacent heat dissipation sheets 21 in each group may be the first length. By disposing the separation distances D to be the same, the cabinet body 2B may be prevented from having a significant temperature gradient in the horizontal direction. However, the present disclosure is not limited thereto.

In other embodiments, when more central processing units (CPU) are stacked in the central area of the cabinet body 2B, the separation distance D between adjacent two heat dissipation sheets 21 in each group of the present disclosure may be the first a length or a second length. Wherein, the first length is smaller than the second length. Further, the separation distance D between the two adjacent heat dissipation sheets 21 located in the central area of the first plate 22 is the first length, and the separation distance D between the two adjacent heat dissipation sheets 21 located in the peripheral area of the first plate 22 is the second length. As a result, the heat dissipation effect of the central area of the first plate 22 may be effectively enhanced by disposing the heat dissipation sheets 21 with higher density in the central area.

In some embodiments, the plurality of heat dissipation sheets 21 may be fixed on the inner surface of the first plate 22 by adhering, fitting, locking, etc., which are well known to a person having ordinary skills in the art. For example, the inner surface of the first plate 22 may be concave with a plurality of engaging grooves, and the thickness of the engaging grooves may be similar to the thickness T of the heat dissipation sheets 21 (for example, may be the same or slightly smaller). The heat dissipation sheets 21 may be stably fixed on the first plate 22 by clamping or interference fit. It should be noted that the methods mentioned above are only examples, and the present disclosure may also adopt other fixing methods, or combine the two fixing methods to obtain a more excellent fixing effect.

In some embodiments, when the heat dissipation door 2A has the first plate 22 and the second plate 23 at the same time, the plurality of heat dissipation sheets 21 may be fixed to the first plate 22 and the second plate 23 at the same time by the methods mentioned above or other suitable methods to obtain an excellent fixation. For example, the plurality of heat dissipation sheets 21 may be connected to the first plate 22 and the second plate 23 by clipping at the same time. Alternatively, the plurality of heat dissipation sheets 21 may be connected to the first plate 22 by clipping and connected to the second plate 23 by adhering.

In some embodiments, the plurality of heat dissipation sheets 21 may be provided with a thermally conductive coating. For example, the dissipation surface 210 of the plurality of heat dissipation sheets 21 may be provided with pure metals, alloys, ceramics, composite materials containing the materials mentioned above, or other suitable materials with good thermal conductivity by electroplating, sputtering, evaporation, coating, etc. to further improve the thermal conductivity of the plurality of heat dissipation sheets 21.

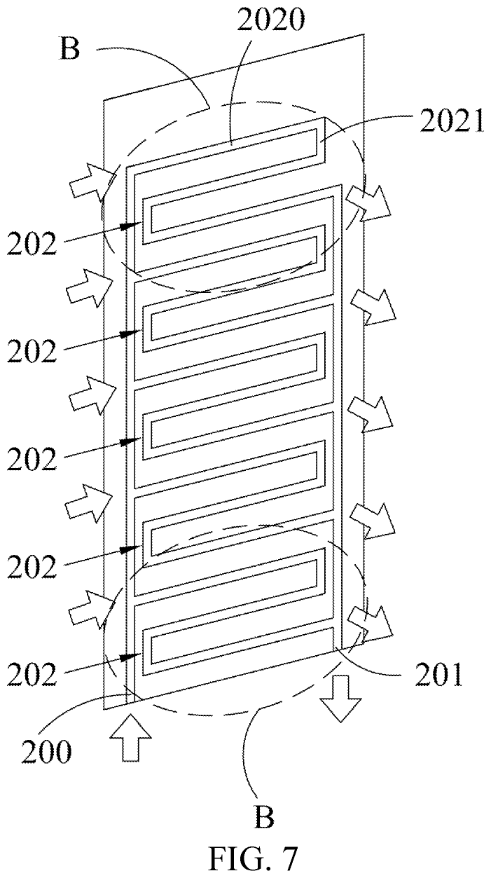

As shown in FIG. 6 and FIG. 7, wherein FIG. 7 is a schematic diagram of a fluid path according to an embodiment of the present disclosure. The heat dissipation tube component 20 is disposed on the side of the first plate 22 adjacent to the cabinet body 2B, and the heat dissipation tube component 20 includes a water inlet 200, a water outlet 201, and a plurality of heat dissipation tubes 202. One end of the water inlet 200 is in fluid communication with the first circulation pipe 100. One end of the water outlet 201 is in fluid communication with the first circulation pipe 100.

In the present disclosure, the positions of the water outlet 201 and the water inlet 200 may be determined according to the position of the heat dissipation door 2A. In order to reduce the length/volume of the first circulation pipe 100, the water outlet 201 and the water inlet 200 are preferably disposed on the side of the heat dissipation door 2A adjacent to the ceiling or the ground, so that the first circulation pipe 100 of the heat dissipation system disposed on the ceiling or the ground may be as close as possible to water outlet 201 and water inlet 200.

In some embodiments, when the first circulation pipe 100 is arranged along the ground, the water outlet 201 and the water inlet 200 are on the side of the first plate 22 adjacent to the ground. More specifically, openings of water outlet 201 and water inlet 200 may be orthogonal to the ground. By disposing the water outlet 201 and the water inlet 200 adjacent to the ground and orthogonal to the ground, the total length of the connecting pipelines connected to the heat dissipation tube component 20 may be effectively reduced. Based on the configuration mentioned above, the present disclosure may further improve the space utilization of the entire device.

In some embodiments, when the first circulation pipe 100 is arranged along the ceiling, the water outlet 201 and the water inlet 200 are on the side of the first plate 22 away from the ground. More specifically, the openings of the water outlet 201 and the water inlet 200 may be adjacent to the ceiling of the computer room to .reduce the total length of the first circulation pipe 100 connected to the heat dissipation tube component 20.

Two ends of each of the plurality of heat dissipation tubes 202 respectively are in fluid communication with the water inlet 200 and the water outlet 201, and each of the plurality of heat dissipation tubes 202 has a plurality of extending sections 2020 and at least one connecting section 2021. The plurality of extending sections 2020 pass through the plurality of dissipation surfaces 210 in sequence, and at least one connecting section 2021 is connected to ends on the same side of adjacent two of the plurality of extending sections 2020. More specifically, the number of the plurality of extending sections 2020 may be N, and the number of connecting sections 2021 may be N−1. For example, the number of extending sections 2020 may be three, and the number of connecting sections 2021 may be two. Alternatively, the number of the plurality of extending sections 2020 may be five, and the number of the connecting sections 2021 may be four.

In some embodiments, the dissipation surface 210 is orthogonal to the plurality of extending sections 2020. In other words, an angle of 90 degrees is formed between the plurality of extending sections 2020 and the dissipation surface 210. However, the present disclosure is not limited thereto. In other embodiments, a specific angle other than 90 degrees may be formed between the plurality of extending sections 2020 and the dissipation surface 210.

In some embodiments, the plurality of heat dissipation sheets 21 are in direct contact with the plurality of heat dissipation tubes 202. In the case where the plurality of heat dissipation sheets 21 and the plurality of heat dissipation tubes 202 are in contact with each other, the rate of heat conduction may be higher. In some embodiments, each heat dissipation sheet 21 may be provided with a plurality of passing holes 211 in advance, and each passing hole 211 corresponds to an extending section 2020 of the heat dissipation tubes 202. Furthermore, peripheral edges of the passing holes 211 and the extending section 2020 are in contact with each other, and a contact area between the heat dissipation sheets 21 and the extending sections 2020 is proportional to the thickness T of the heat dissipation sheets 21 (ie, the thickness of the peripheral edge). Therefore, by increasing the thickness T of the heat dissipation sheets 21 to increase the area of the periphery of the passing holes 211 in contact with the extending sections 2020, the heat conduction rate may be increased more effectively.

In some embodiments, the plurality of heat dissipation tubes 202 are disposed on the first plate 22 along the vertical direction in sequence. By disposing the plurality of heat dissipation tubes 202 in sequence, the heat dissipation door 2A may be divided into a plurality of heat dissipation sections B. When more heat dissipation sections B are formed, the temperature of the entire heat dissipation door 1 shows frequent periodic changes. For example, a low temperature (the extending section 2020 of the first heat dissipation tube 202 close to the water inlet 200), a medium temperature (the extending section 2020 of the first heat dissipation tubes 202 close to the water outlet 201), a low temperature (the extending section 2020 of the first heat dissipation tube 202 close to the water outlet 201), and a medium temperature (the extending section 2020 of the first heat dissipation tubes 202 close to the water outlet 201) are shown.

In contrast, a significant temperature gradient is generated by the heat dissipation door with only one heat dissipation section in the prior art. For example, a low temperature (the extending section 2020 of the heat dissipation tube 202 closest to water inlet 200), a medium temperature (the extending section 2020 of the heat dissipation tube 202 secondary close to the water inlet 200), a high temperature (the extending section 2020 of heat dissipation tube 202 secondary close to the water outlet 201) and ultra-high temperature (the extending section 2020 of the heat dissipation tube 202 closest to the water outlet 201) are shown. In contrast, the heat dissipation door 2A of the present disclosure with multiple heat dissipation sections B may effectively reduce the significant temperature gradient.

As shown in FIG. 6, in some embodiments, the heat dissipation door 2A further includes a plurality of fans 24. The plurality of fans 24 is disposed between the heat dissipation sheets 21 and the cabinet body 2B and corresponds to the plurality of heat dissipation sheets 21. That is, the plurality of fans 24 may be provided inside the cabinet. Specifically, the fans 24 are configured to draw hot gas inside the cabinet body 2B to the outside of the heat dissipation door 2A. As a result, the hot gas in the cabinet is cooled when passing through the heat dissipation tubes 202 and the heat dissipation sheets 21. Therefore, the hot gas becomes cool gas and leaves the heat dissipation door 2A in a low-temperature state. Furthermore, gas outside the heat dissipation door 2A is pushed to move away from the heat dissipation door 2A. In addition, when the gas in the cabinet leaves the heat dissipation door 2A and moves in a direction away from the heat dissipation door 2A, gas in the external environment may enter the cabinet body 2B from the side of the cabinet body 2B away from the heat dissipation door 2A. A good heat dissipation cycle is formed.

In some embodiments, the plurality of fans 24 are disposed on the outer side of the first plate 22 and corresponds to the plurality of heat dissipation sheets 21. That is, the plurality of fans 14 may also be attached to the cabinet 2. In other embodiments, the plurality of fans 24 may also be disposed between the heat dissipation sheets 21 and the cabinet body 2B and outside the first plate 22 at the same time, so as to obtain a better suction effect. The operation of the plurality of fans 24 is similar or the same as that described above, and the description is omitted.

In some embodiments, when the heat dissipation door 2A further includes the plurality of fans 24, the first plate 22 and the second plate 23 respectively have a plurality of air holes. By disposing the air holes, the hot gas in the cabinet is easier to be driven by the fans 24 and leave the cabinet through the heat dissipation door 2A. In some embodiments, in order to improve the stability of the air intake, the plurality of air holes are spaced apart from each other by a fixed distance. In some embodiments, in order to improve the local heat dissipation effect, the plurality of air holes are spaced apart from each other at different distances. For example, the area that needs to improve the heat dissipation effect may have more air holes correspondingly.

In some embodiments, the heat dissipation door 2A of the cabinet further includes a roller 25, and the roller 25 is disposed on the side of the first plate 22 adjacent to the ground. Since a large number of heat dissipation components such as heat dissipation tubes 202 and heat dissipation sheets 21 are provided in the heat dissipation door 2A of the present disclosure, the door must have a certain weight. Therefore, by providing the roller 25, the heat dissipation door 2A of the present disclosure may be easily opened or closed. It should be noted that, although one roller 25 is illustrated in the figure of the present disclosure, the present disclosure is not limited thereto. In other embodiments, the number of rollers 25 may be two, three, or more than three, which may be determined according to actual usage.

In summary, the heat exchange system transfers the heat out from the cabinet through the first circulation pipe and transfers the heat to the chilling machine through the second circulation pipe, thereby effectively dissipating heat. Wherein, there is only heat transfer between the first circulation pipe and the second circulation pipe without fluid communication. In this way, the second fluid flowing between the second circulation pipe and the chilling machine will not pollute the first fluid flowing between the first circulation pipe and the cabinet, thereby effectively extending the useful life of the entire heat exchange system. Therefore, the present disclosure realizes a heat exchange system that may effectively dissipate heat and operate continuously and stably.

Although the present disclosure has been explained in relation to its preferred embodiment, it does not intend to limit the present disclosure. It will be apparent to those skilled in the art having regard to this present disclosure that other modifications of the exemplary embodiments beyond those embodiments specifically described here may be made without departing from the spirit of the invention. Accordingly, such modifications are considered within the scope of the invention as limited solely by the appended claims.

What is claimed is:

1. A heat exchange system, comprising:
a cabinet, wherein the cabinet comprises a heat dissipation door and a cabinet body, and the heat dissipation door is disposed on the cabinet body; and
a heat exchange apparatus partially disposed in the cabinet body and comprising a heat exchange module, wherein the heat exchange module comprises:
a first circulation pipe in fluid communication with a heat dissipation tube component in the heat dissipation door; and
a cooling device comprising a second circulation pipe and a chilling machine, a part of the second circulation pipe is penetrated in the chilling machine to transfer heat to the chilling machine, the first circulation pipe is heat-exchanged with but not in fluid communication with the second circulation pipe.

2. The heat exchange system of claim 1, wherein the heat exchange apparatus further comprises:
a drive module connected to the heat exchange module and configured to drive a first fluid in the first circulation pipe to flow along the first circulation pipe;
a buffer module in fluid communication with the first circulation pipe, wherein the buffer module comprises a control valve and a storage space, the control valve is located between the first circulation pipe and the storage space; and
a control module disposed in the cabinet body and electrically connected to the drive module and the buffer module, wherein the control module comprises a sensing device, the control module controls the control valve to open or close according to a sensing signal sent by the sensing device and controls the drive module according to the sensing signal sent by the sensing device.

3. The heat exchange system of claim 2, wherein the control module comprises:
a calculate sub-module receiving the sensing signal from the sensing device, generating a control signal according to the sensing signal, and sending the control signal to the buffer module and/or the drive module; and
a record sub-module receiving the sensing signal from the sensing device and storing a voltage information, a current information, a fluid pressure information, a fluid temperature information, and a fluid flow information of the sensing signal.

4. The heat exchange system of claim 2, wherein the drive module comprises a drive pump, the drive pump is disposed in the first circulation pipe and drives the first fluid in the first circulation pipe.

5. The heat exchange system of claim 4, wherein the drive pump is provided in plurality, at least one of the plurality of the drive pumps is in a running state, and at least one of the plurality of the drive pumps is in a closed state.

6. The heat exchange system of claim 1, wherein the heat dissipation door comprises:
a first plate;
a plurality of heat dissipation sheets disposed on one side of the first plate adjacent to the cabinet body, wherein each of the plurality of heat dissipation sheets has a heat dissipation surface; and
the heat dissipation tube component disposed on one side of the first plate adjacent to the cabinet body and comprising:
a water inlet, wherein one end of the water inlet is in fluid communication with the first circulation pipe;
a water outlet, wherein one end of the water outlet is in fluid communication with the first circulation pipe; and
a plurality of heat dissipation tubes, wherein two ends of each of the plurality of heat dissipation tubes respectively are in fluid communication with the water inlet and the water outlet, each of the plurality of heat dissipation tubes has a plurality of extending sections and at least one connecting section, the plurality of extending sections passes through the heat dissipation surfaces in sequence, and at least one connecting section is connected to ends on the same side of two adjacent extending sections.

7. The heat exchange system of claim 6, wherein the dissipation surfaces are orthogonal to the plurality of extending sections.

8. The heat exchange system of claim 6, wherein the plurality of heat dissipation sheets are in direct contact with the plurality of heat dissipation tubes.

9. The heat exchange system of claim 6, wherein the plurality of heat dissipation tubes are sequentially disposed on the first plate in a vertical direction.

10. The heat exchange system of claim 6, wherein the water outlet and the water inlet are on a side of the first plate adjacent to a ground or on a side of the first plate away from the ground.

11. The heat exchange system of claim 6, wherein the heat dissipation door further comprises a plurality of fans disposed between the plurality of heat dissipation sheets and the cabinet body or outside the first plate, and the plurality of fans correspond to the plurality of heat dissipation sheets.

12. The heat dissipation door of cabinet of claim 1, wherein the heat dissipation door further comprises a roller, wherein the roller is disposed on a side of the first plate adjacent to a ground.

13. The heat exchange system of claim 6, wherein the heat dissipation door further comprises a second plate body, the second plate body is between the cabinet body and the first plate, an accommodating space is formed between the second plate body and the first plate, and the plurality of heat dissipation tubes and the plurality of heat dissipation sheets are in the accommodating space.

14. The heat exchange system of claim 13, wherein the first plate and the second plate respectively have a plurality of air holes.
